(19) United States
(12) Patent Application Publication
(10) Pub. No.: US 2025/0173124 A1
(43) Pub. Date: May 29, 2025

(54) GENERALIZED DISTRIBUTION TRUE RANDOM NUMBER GENERATOR (TRNG) WITH AUTONOMOUSLY LEARNING PROBABILISTIC CIRCUITS

(71) Applicant: Intel Corporation, Santa Clara, CA (US)

(72) Inventors: Punyashloka Debashis, Hillsboro, OR (US); Hai Li, Portland, OR (US); Dmitri Evgenievich Nikonov, Beaverton, OR (US); Mahendra DC, Portland, OR (US); Ian Alexander Young, Olympia, WA (US)

(73) Assignee: Intel Corporation, Santa Clara, CA (US)

(21) Appl. No.: 18/520,216

(22) Filed: Nov. 27, 2023

(51) Int. Cl. G06F 7/58; H10N 50/10

(52) U.S. Cl. CPC G06F 7/588; H10N 50/10

(57) ABSTRACT

Apparatus and methods for true random number generation (RNG) with a target probability distribution with autonomously learning probabilistic circuits. The apparatus utilizes, for individual probabilistic bits (p-bits), a magnetic tunnel junction (MTJ) resistor. The apparatus also uses circuitry to harness the fluctuating resistance of the MTJ resistor to generate high-quality random numbers. The hardware footprint depends on the precision required and is smaller than an equally precise or high-quality RNG implemented using CMOS hardware. Post-processing is not required on the generated random numbers.

### BACKGROUND

A variety of computing applications, such as Bayesian neural networks, require the generation of random numbers with various probability distributions. Often, a circuit or module in a computing system is a dedicated random number generator (RNG). The generation of high-quality random numbers can disproportionately consume the system's energy and be very costly. Accordingly, improved random number generator (RNG) architectures and methodologies are desirable.

### BRIEF DESCRIPTION OF THE DRAWINGS

FIG. 1 is a schematic diagram of a generalized distribution true RNG system.

FIG. 2 and FIG. 3 provide a more detailed view of embodiments of components of the RNG system.

FIG. 4 is an exemplary process flow for a generalized distribution true RNG system, as defined herein.

FIG. 5 is a top view of a wafer and dies that may embody integrated circuit components, in accordance with any of the embodiments disclosed herein.

FIG. 6 is a simplified cross-sectional side view showing an implementation of an integrated circuit component on a die that may be included in any of the embodiments disclosed herein.

FIG. 7 is a cross-sectional side view of a microelectronic assembly that may include any of the embodiments disclosed herein.

FIG. 8 is a block diagram of an example electrical device that may include any of the embodiments disclosed herein.

### DETAILED DESCRIPTION

A variety of computing applications rely on random number generation, e.g., in neural networks. In deterministic neural net applications, weights connecting the neurons are fixed. However, in another class of neural nets, the weights are expected to be drawn from a probability distribution. For example, a Bayesian neural network expects a variety of distributions of random numbers in each iteration. Often, a circuit or module in such a computing system is a dedicated random number generator (RNG).

One proposed solution generates random numbers using algorithms that run on general purpose central processing units (CPUs). However, generating high-quality random numbers using general purpose CPUs requires a big footprint, and high energy and hardware cost. Furthermore, this solution requires compute intensive post-processing to the tailor the probability distribution of the generated random numbers. Therefore, the demand for continued improvements to RNGs drives ongoing research in this area.

Embodiments provide a technical solution to this technical problem and other related enhancements, in the form of apparatus and methods for true random number generation with autonomously learning probabilistic circuits. Embodiments advantageously employ the physics of the implemented hardware to harness ambient noise and generate high-quality random numbers therefrom. The hardware footprint depends on the precision required and is always much smaller than an equally precise or high-quality RNG implemented using CMOS hardware. Additionally, embodiments do not require post-processing on the generated random numbers, which is an improvement over similar RNGs implemented using CMOS hardware.

The provided embodiments can be detected in various ways. Utilizing techniques such as, a scanning electron microscope or transmission electron microscope (TEM), electron energy loss spectroscopy (EELS), or energy dispersive X-ray (EDX), to identify the herein defined structures and probabilistic bits. A more detailed description of the embodiments follows.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Terms or values modified by the word “substantially” include arrangements, orientations, spacings, or positions that vary by plus or minus 20% (inclusive) from the meaning of the unmodified term or value. Terms or values modified by the word “about” include values inclusive of 10% less than the term or value to inclusive of 10% greater than the term or value.

Example embodiments are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

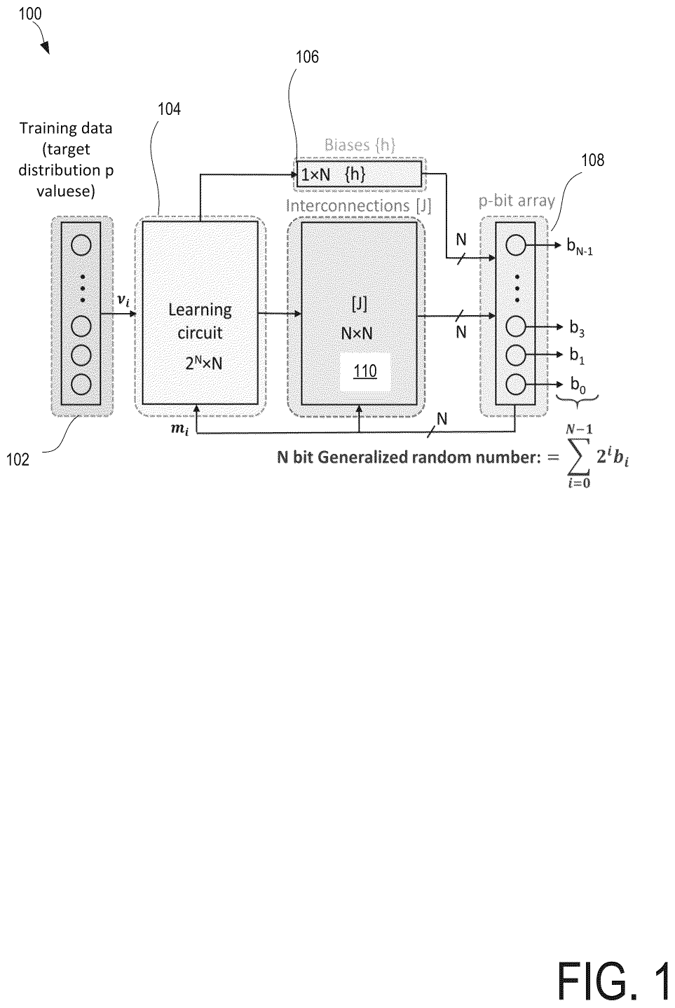

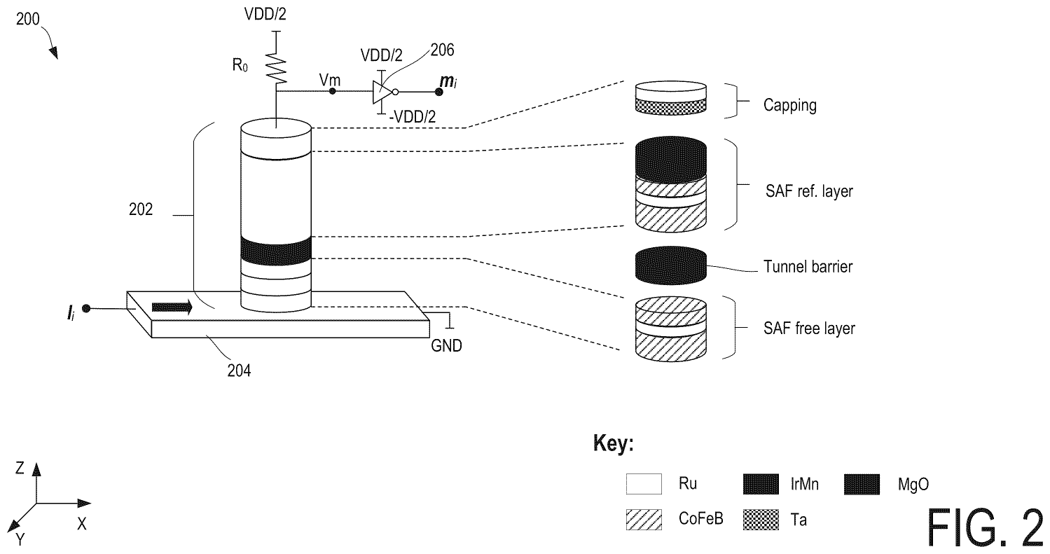

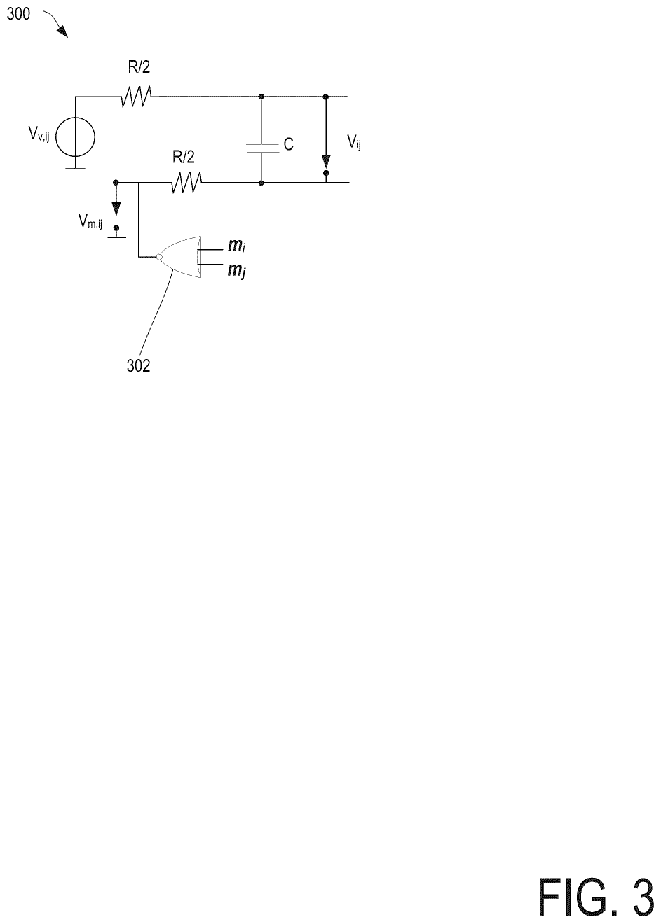

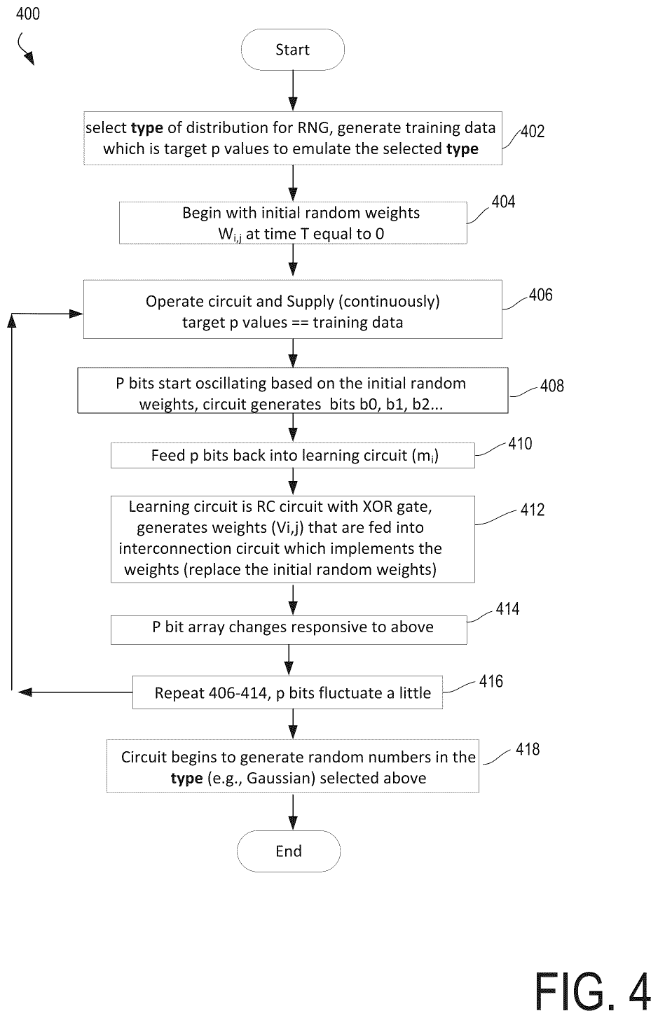

As an overview of the drawings, FIG. 1 is a schematic diagram of a generalized distribution true RNG system 100 (hereinafter shortened to “RNG system 100” and/or “system 100”). FIG. 2 and FIG. 3 provide a more detailed view of components of the RNG system 100, and the operation of the RNG system 100 is described in more detail in connection with the flow diagram 400 of FIG. 4.

As shown in the embodiment of FIG. 1, the RNG system 100 is arranged for a N bit generalized random number. The N bits of a binary number define a decimal number used for the weight on a node in a neural net. The training data, which are the target distribution p values 102 provide input vᵢ to the learning circuit 104. The learning circuit 104 is arranged as 2^{N}×N, and also receives input mi from the p-bit array 108. Output from the learning circuit 104 is fed into biases module 106 and the interconnection circuitry 110. The biases module 106 is arranged with {h} members of size 1×N. The biases module 106 receives input from the learning circuit and provides input of size N to the p-bit array 108.

The interconnection circuitry 110 is arranged as J members of size N×N. The interconnection circuitry 110 receives N p-bit values from the p-bit array 108 and outputs N values to the P-bit array.

The p-bit array 108 generates N binary bits, identified as b₀ to b_{N-1}. The N binary bits are non-uniform, which is a function/characteristic of the respective magnetic tunnel junction (MTJ) resistors implemented therein (see, e.g., FIG. 2). As is described in more detail below, a decimal number (output) generated from the N p-bits can be designed to follow a general distribution (e.g., N bit generalized random number), or any other target distribution. The interconnections [J] and biases {h} control the probability of the N p-bits.

The learning circuit 104 works by comparing the instantaneous p-bit values and values from the target distribution and applies a learning rule to thereby generate the required weight values for the interconnection circuitry 110. Once the learning is complete, the system 100 generates RNGs with the target distribution.

FIG. 2 illustrates an exemplary embodiment of an individual p-bit 200, representative of the plurality of p-bits in the p-bit array 108. The exemplary p-bit 200 implements a thermally unstable magnetic tunnel junction (MTJ). Current Iᵢ is provided to the input of the i^{th} p-bit by the interconnection and the bias modules based on the state of the other p-bits and the values of the interconnection and bias elements in those modules. This input current flows through a spin-orbit torque (SOT) layer acting as a bottom electrode (BE) 204 that is grounded and has, substantially orthogonal thereto, a MTJ resistor, denoted R_{MTJ} 202. In various embodiments of the p-bit 200, circuitry is implemented to use a fluctuating resistance of the magnetic tunnel junction in the MTJ resistor as a source of non-uniform random values. In FIG. 2, the circuitry includes reference resistor R₀ and inverter 206. At the upper page in the illustration, voltage of VDD/2 is supplied at the first terminal of a resistor R₀ and at the first terminal of an inverter. The inverter is supplied at a second terminal with (−Vdd/2). The VDD values can be standard CMOS VDD values. The second terminal of the reference resistor R₀ is in electrical communication with an upper (in the diagram) top electrode (the capping) of the MTJ resistor, R_{MTJ}. Stated differently, reference resistor R₀ and R_{MTJ} are in series; the voltage therebetween, at the top electrode of R_{MTJ}, is denoted Vₘ. Recall, R_{MTJ} has a fluctuating resistance. In various embodiments, the resistance of the MTJ resistor fluctuates at a timescale of less than 10 nanoseconds. In practice, the resistance value of R₀ may be fixed to an average resistance value of R_{MTJ} 202. The output of the inverter is mi (collectively, there are N mᵢ), which are fed into the learning circuit 104.

With reference to the key in the bottom right of FIG. 2, R_{MTJ} 202 may comprise the following exemplary materials and arrangement. The top electrode or capping layer may comprise Ru (Ruthenium) and Ta (Tantalum), followed by a body that includes a reference synthetic antiferromagnetic (SAF) layer, a tunnel barrier, and a SAF-free layer. The SAF reference layer may comprise an antiferromagnetic metal, such as IRMn (Iridium and Manganese), followed by a “sandwich” comprising CoFeB (Cobalt, Iron, Boron), followed by Ru, followed by another CoFeB layer. The Tunnel barrier may comprise MgO (magnesium oxide). A lower end of R_{MTJ} 202, found under the tunnel barrier, may be another sandwich of CoFeB, Ru, and CoFeB layers, but the antiferromagnetic metal is not employed, hence this region is not pinned by the exchange coupling to the antiferromagnetic metal. Hence it is being referred to as “SAF free layer.” Note the IrMn is only in the SAF ref. layer.

The Ru and the Ta layers in the top electrode may each have a thickness in a range of 2 nanometers to 20 nanometers (+/−20%). The IrMn layer may have a thickness of 5 nanometers to 20 nanometers (+/−20%). The MgO layer may have a thickness of 1-2 nanometers (+/−20%). In the CoFeB “sandwiches,” the two CoFeB may have a thickness of 1.5 nanometers (+/−20%), and the Ru layer may have a thickness of 0.8 nanometers (+/−10%).

The learning circuit 104 can implement any appropriate learning rule to achieve a target distribution. One example learning rule, shown in Equation 1, is a simplified version of the gradient ascent approach to optimize the maximum likelihood function. In Equation 1, ε corresponds to the learning rate and λ, called the regularization parameter, is a “knob” typically varied to improve the learning convergence. The term vᵢvⱼ is the correlation between the ith and the jth entry of the training input from the target distribution p values 102. The term mᵢmⱼ corresponds to the correlation of the ith and the jth p-bit.

$${W}_{ij} ( t + Δ t ) = {W}_{ij} ( t ) + ϵ [ {v}_{i} {v}_{j} - {m}_{i} {m}_{j} - λ {W}_{ij} ( t ) ] . \qquad Equation 1$$

$$\frac{{dW}_{ij}}{dt} = \frac{{v}_{i} {v}_{j} - {m}_{i} {m}_{j} - λ {W}_{ij} ( t )}{{τ}_{L}} \qquad Equation 2$$

Equation 2 is the time continuous time version of Equation 1. The vᵢvⱼ values are converted to resistance values for a circuit implementation such as is shown in FIG. 3 and with Equation 3.

$$C \frac{{dV}_{ij}}{dt} = \frac{{V}_{v , ij} - {V}_{m , ij} - {V}_{ij}}{R} \qquad Equation 3$$

In an embodiment, the vᵢvⱼ values are converted to resistance values using programmable resistor banks. Turning now to FIG. 3, and with continued reference to FIGS. 1-2, building the circuit 300 enables solving the Equations 1 and 3. The exclusive OR gate 302 has input mᵢmⱼ, corresponding to the correlation of the ith and the jth p-bit, as mentioned.

FIG. 4 is an exemplary process flow for a true RNG system. At 402, the type of distribution for the RNG is selected. In an example, the type is a Gaussian generalized distribution RNG. As part of this selection, training data is generated or obtained. For example, a tool such as MatLab can be used to generate the training data. At 404, the RNG is populated with initial random weights at the nodes. The initial random weights W_{i,j} are at time T equal to zero.

At 406, the circuit begins operating. The training data are the target p values in operation, and the circuit operates continuously referencing the training data. At 408, the p-bits start fluctuating based on the initial random weights, and the circuit generates p-bits b0, b1, b2 . . . to bN−1.

At 410, the process feeds p-bits back into learning circuit 104 (indicated individually as mi, the output of the p-bit 200. At 412, the learning circuit 104, e.g., implemented as the circuit 300 of FIG. 3 (RC circuit with XOR gate) generates weights (Vi,j) that are fed into interconnection circuitry 110; and, the interconnection circuit 110 implements the generated weights across the nodes (i.e., by replacing initial random weights with the generated weights).

At 414, the p-bit array 108 changes responsive to the changes in the interconnection circuit 110 at 412.

In operation, the process may continue to cycle through or repeat 406-414, during which time, the p-bits can fluctuate. The plurality of p-bits represent an n-bit number. At 418, the circuit begins to generate random numbers in the type (e.g., an n-bit number with a Gaussian generalized distribution) selected above. Accordingly, people with skill in the art understand that embodiments employ autonomously learning probabilistic circuits.

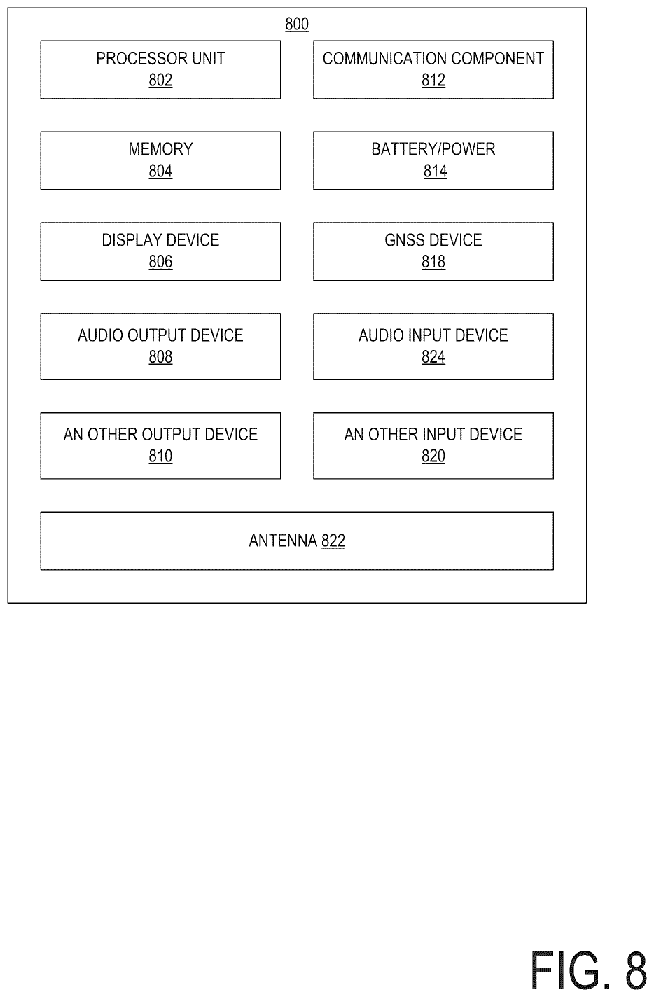

A package assembly comprising the above true RNG architecture may further be assembled into a device or product; the device or product may further include a power supply, a communication system/component, or any of a variety of other components, as illustrated in FIG. 8.

Thus, apparatus and methods for true random number generator (RNG) with autonomously learning probabilistic circuits have been described. Embodiments advantageously employ the physics of the implemented hardware to harness ambient noise, the fluctuations in resistance of the MTJ resistor, and generate high-quality random numbers therefrom. In various embodiments, an enormous real estate savings may be realized, for example, the implementation of a 16-bit RNG can take on the order of 50 transistors, whereas the CMOS solution might have taken more like 1000 transistors. An embodiment of the provided architecture may be included in an integrated circuit component, be it packaged or unpackaged. In some scenarios, embodiments are implemented as a means for sensing velocity (in velocity sensor systems), a means for sending movement (in movement sensor systems), or the like. The following description illustrates context for usage and application of provided embodiments.

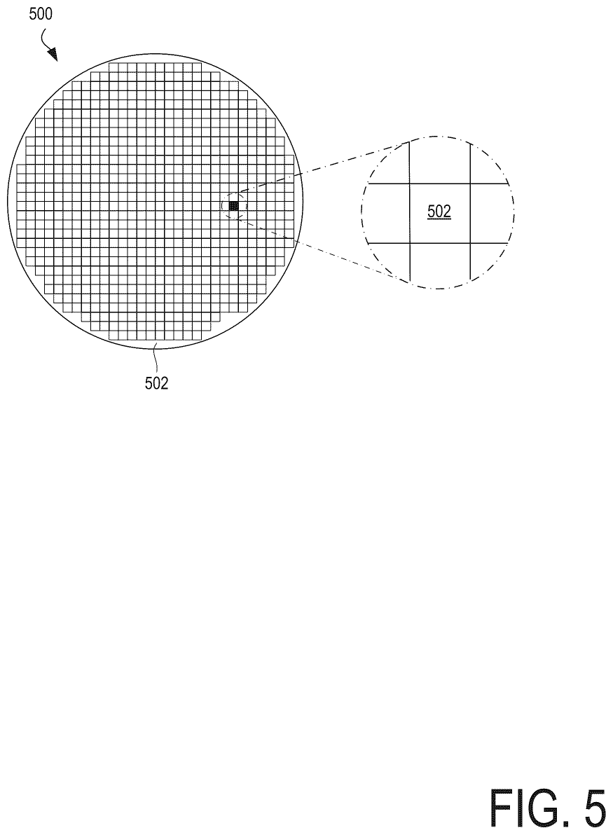

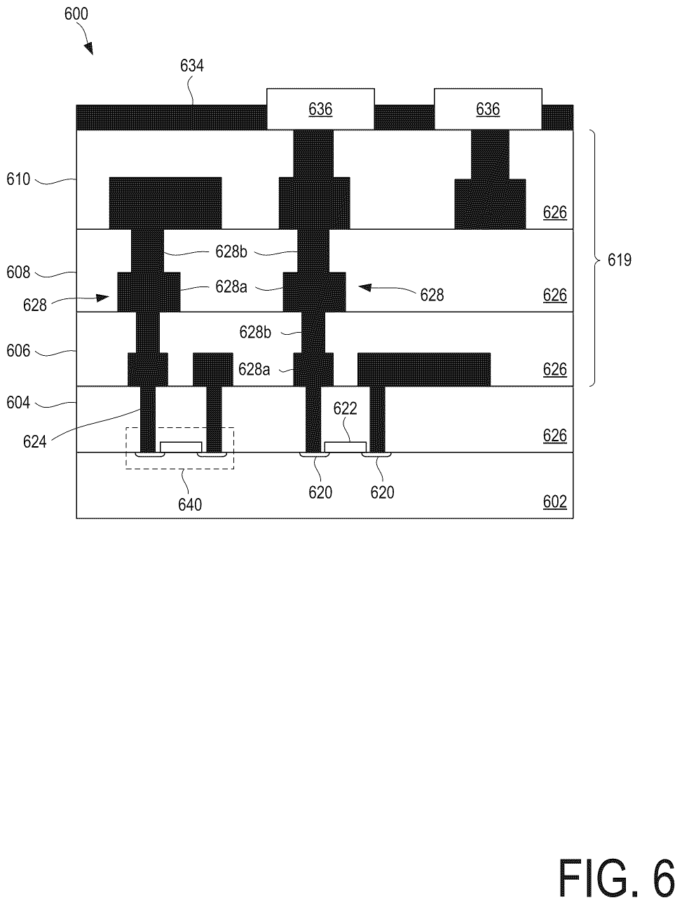

FIG. 5 is a top view of a wafer 500 and dies 502 that may embody integrated circuit components, in accordance with any of the embodiments disclosed herein. The wafer 500 may be composed of semiconductor material and may include one or more die 502 having integrated circuit structures formed on a surface of the wafer 500. The individual circuit structures on the die 502 may embody/implement an integrated circuit product or semiconductor product. After the fabrication of the semiconductor product is complete, the wafer 500 may undergo a singulation process in which the die 502 are separated from one another to provide discrete “chips” of the integrated circuit product. Respective die 502 may be any of the die disclosed herein. The die 502 may include one or more transistors (e.g., transistors referred to above, and/or some of the transistors 640 of FIG. 6, discussed below), supporting circuitry to route electrical signals to the transistors, passive components (e.g., signal traces, resistors, capacitors, or inductors), and/or any other integrated circuit components.

In some embodiments, in addition to or in conjunction with the above description, the wafer 500 or the die 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processor unit (e.g., the processor unit 802 of FIG. 8) or other logic that is configured to store information in the memory devices or execute instructions stored in the memory array. Various ones of the microelectronics assemblies 700 disclosed herein may be manufactured using a die-to-wafer assembly technique in which some dies are attached to a wafer 500 that include others of the dies 502, and the wafer 500 is subsequently singulated.

FIG. 6 is a cross-sectional side view of an integrated circuit component 600 implemented on a die that may be included in any of the that may embody integrated circuit components, in accordance with any of the embodiments disclosed herein. One or more of the integrated circuit components 600 may be included in one or more dies 502 (FIG. 5). The integrated circuit component 600 may be formed on a die substrate 602 (e.g., the wafer 500 of FIG. 5) and may be included in a die (e.g., the die 502 of FIG. 5). The die substrate 602 may be a semiconductor substrate composed of semiconductor material systems including, for example, n-type or p-type materials systems (or a combination of both). The die substrate 602 may include, for example, a crystalline substrate formed using a bulk silicon or a silicon-on-insulator (SOI) substructure. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit component 600 may be used. The die substrate 602 may be part of a singulated die (e.g., the dies 502 of FIG. 5) or a wafer (e.g., the wafer 500 of FIG. 5).

The integrated circuit component 600 may include one or more device layers 604 disposed on the die substrate 602. The device layer 604 may include features of one or more transistors 640 (e.g., metal oxide semiconductor field-effect transistors (MOSFETs)) formed on the die substrate 602. The transistors 640 may include, for example, one or more source and/or drain (S/D) regions 620, a gate 622 to control current flow between the S/D regions 620, and one or more S/D contacts 624 to route electrical signals to/from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Continuing with FIG. 6, a transistor 640 may include a gate 622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 640 along the source-channel-drain direction, the gate electrode may consist of a U-shaped structure that includes a bottom portion substantially parallel to the surface of the die substrate 602 and two sidewall portions that are substantially perpendicular to the top surface of the die substrate 602. In other embodiments, at least one of the metal layers that form the gate electrode may simply be a planar layer that is substantially parallel to the top surface of the die substrate 602 and does not include sidewall portions substantially perpendicular to the top surface of the die substrate 602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 620 may be formed within the die substrate 602 adjacent to the gate 622 of individual transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse farther into the die substrate 602 may follow the ion-implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or input/output (I/O) signals, may be routed to and/or from the devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with the interconnect structures 628 of the interconnect layers 606-610. The one or more interconnect layers 606-610 may form a metallization stack (also referred to as an “ILD stack”) 619 of the integrated circuit component 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit components having more or fewer interconnect layers than depicted.

In some embodiments, the interconnect structures 628 may include lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page. The vias 628b may be arranged to route electrical signals in a direction of a plane that is substantially perpendicular to the surface of the die substrate 602 upon which the device layer 604 is formed. In some embodiments, the vias 628b may electrically couple lines 628a of different interconnect layers 606-610 together.

The interconnect layers 606-610 may include a dielectric material 626 disposed between the interconnect structures 628, as shown in FIG. 6. In some embodiments, dielectric material 626 disposed between the interconnect structures 628 in different ones of the interconnect layers 606-610 may have different compositions; in other embodiments, the composition of the dielectric material 626 between different interconnect layers 606-610 may be the same. The device layer 604 may include a dielectric material 626 disposed between the transistors 640 and a bottom layer of the metallization stack as well. The dielectric material 626 included in the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (referred to as Metal 1 or “M1”) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (referred to as Metal 2 or “M2”) may be formed directly on the first interconnect layer 606. In some embodiments, the second interconnect layer 608 may include via 628b to couple the lines that are interconnect structures 628 of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (referred to as Metal 3 or “M3”) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit component 600 (i.e., farther away from the device layer 604) may be thicker that the interconnect layers that are lower in the metallization stack 619, with lines 628a and vias 628b in the higher interconnect layers being thicker than those in the lower interconnect layers.

The integrated circuit component 600 may include a solder resist material 634 (e.g., polyimide or similar material) and one or more conductive contacts 636 formed on the interconnect layers 606-610. In FIG. 6, the conductive contacts 636 are illustrated as taking the form of bond pads. The conductive contacts 636 may be electrically coupled with the interconnect structures 628 and configured to route the electrical signals of the transistor(s) 640 to external devices. For example, solder bonds may be formed on the one or more conductive contacts 636 to mechanically and/or electrically couple an integrated circuit die including the integrated circuit component 600 with another component (e.g., a printed circuit board). The integrated circuit component 600 may include additional or alternate structures to route the electrical signals from the interconnect layers 606-610; for example, the conductive contacts 636 may include other analogous features (e.g., posts) that route the electrical signals to external components.

In some embodiments in which the integrated circuit component 600 is double-sided, the integrated circuit component 600 may include another metallization stack (not shown) on the opposite side of the device layer(s) 604. This metallization stack may include multiple interconnect layers as discussed above with reference to the interconnect layers 606-610, to provide conductive pathways (e.g., including conductive lines and vias) between the device layer(s) 604 and additional conductive contacts (not shown) on the opposite side of the integrated circuit component 600 from the conductive contacts 636.

In other embodiments in which the integrated circuit component 600 is a double-sided, the integrated circuit component 600 may include one or more through silicon vias (TSVs) through the die substrate 602; these TSVs may make contact with the device layer(s) 604, and may provide conductive pathways between the device layer(s) 604 and additional conductive contacts (not shown) on the opposite side of the integrated circuit component 600 from the conductive contacts 636. In some embodiments, TSVs extending through the substrate can be used for routing power and ground signals from conductive contacts on the opposite side of the integrated circuit component 600 from the conductive contacts 636 to the transistors 640 and any other components integrated into the die of the integrated circuit component 600, and the metallization stack 619 can be used to route I/O signals from the conductive contacts 636 to transistors 640 and any other components integrated into the die of the integrated circuit component 600.

Multiple integrated circuit components 600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

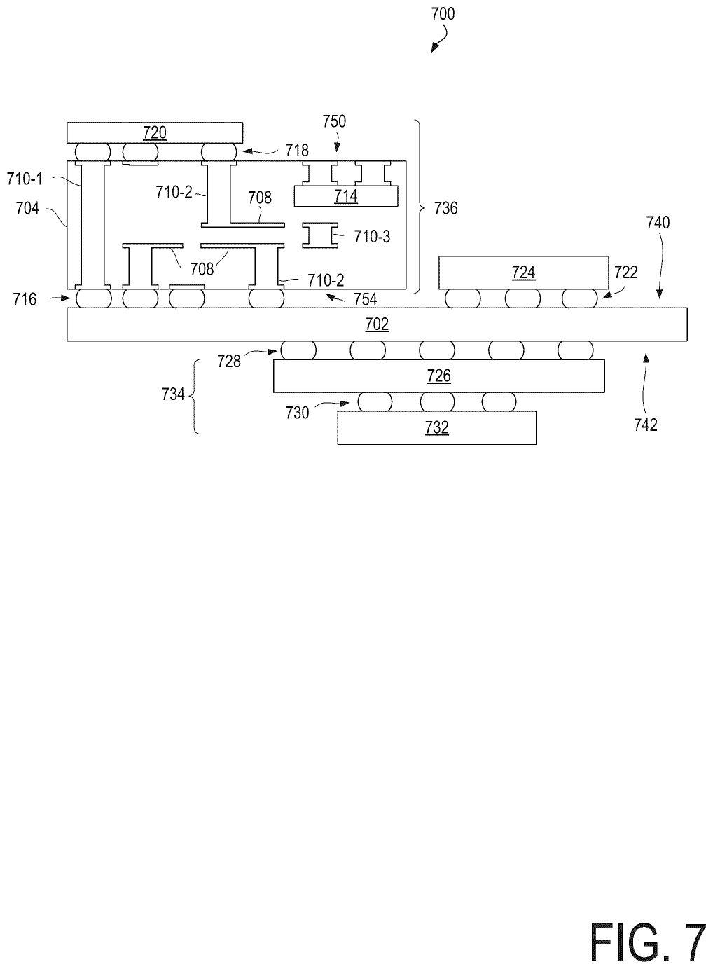

FIG. 7 is a cross-sectional side view of a “package assembly” or microelectronics assembly 700 that may include an apparatus or structure disclosed herein. The microelectronics assembly 700 includes a number of components disposed on a circuit board 702 (which may be a motherboard, system board, mainboard, etc.). The microelectronics assembly 700 includes components disposed on a first face 740 of the circuit board 702 and an opposing second face 742 of the circuit board 702; generally, components may be disposed on one or both faces 740 and 742.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other embodiments, the circuit board 702 may be a non-PCB substrate. In some embodiments the circuit board 702 may be, for example PCB. The microelectronics assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 716 may serve as the coupling components illustrated or described for any of the substrate assembly or substrate assembly components described herein, as appropriate.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged or unpacked integrated circuit product that includes one or more integrated circuit dies (e.g., the die 502 of FIG. 5, the integrated circuit component 600 of FIG. 6) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit die, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the embodiment illustrated in FIG. 7, the integrated circuit component 720 and the circuit board 702 are attached to opposing sides of the interposer 704; in other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias 710, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on the first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art. In embodiments where the interposer is a non-printed circuit board

The microelectronics assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The microelectronics assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

FIG. 8 is a block diagram of an example electrical device 800 that may include an apparatus and/or structure disclosed herein. For example, any suitable ones of the components of the electrical device 800 may include one or more of the apparatus (e.g., 100, 130, 140), structures (e.g., 208, 214, 216), microelectronics assemblies 700, integrated circuit components, or integrated circuit dies 502 disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die. In some embodiments, some or all of the components included in the electrical device 800 may be enclosed in a housing 826.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802, as defined herein. The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include another output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include another input device 820 (or corresponding interface circuitry, as discussed above). Examples of the other input device 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an Ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used herein, the terms “processing circuitry,” “processor unit,” “processing unit,” or “processor” may refer to any device or portion of a device that processes electronic data from registers and/or memory to transform that electronic data into other electronic data that may be stored in registers and/or memory. A processor unit may be a system-on-a-chip (SOC), and/or include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

As used herein, the term “electronic component” can refer to an active electronic circuit (e.g., a processing unit, a memory, a storage device, a field effect transistor (FET)) or a passive electronic component (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (see, e.g., FIG. 8 discussion for processor unit 802 definition), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (also shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS) component; the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

As used in this application and the claims, a list of items joined by the term “at least one of” can mean any combination of the listed terms. For example, the phrase “at least one of A, B and C” can mean A; B; C; A and B; A and C; B and C; or A, B, and C. Similarly, as used in this application and the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and sub-combinations with one another. The disclosed methods, apparatuses, and systems are not limited to any specific aspect or feature or combination thereof, nor do the disclosed embodiments require that any one or more specific advantages be present, or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following Examples pertain to additional embodiments of technologies disclosed herein.
Example 1 is a random number generator (RNG) comprising: a plurality of probabilistic bits (p-bits), wherein individual p-bits comprise: a spin-orbit torque (SOT) layer; a magnetic tunnel junction (MTJ) resistor attached orthogonal to the SOT layer; and circuitry to convert a fluctuating resistance of the MTJ resistor into a binary value.
Example 2 includes the subject matter of Example 1, wherein the circuitry comprises: a reference resistor having a first terminal, a second terminal, and a resistance equal to an average resistance of the MTJ resistor;
a voltage source; the reference resistor attached at the first terminal to the voltage source, and attached at the second terminal to the MTJ resistor; a ground source attached to the SOT layer; and
an inverter to invert a voltage at the second terminal.
Example 3 includes the subject matter of Example 1 or Example 2, wherein the MTJ resistor comprises a tunnel barrier layer sandwiched between a synthetic antiferromagnetic (SAF) layer and a SAF-free layer.
Example 4 includes the subject matter of Example 3, wherein the tunnel barrier layer comprises MgO (magnesium oxide).
Example 5 includes the subject matter of any one of Examples 2-4, wherein the MTJ resistor further comprises a layer comprising Ru (Ruthenium) and Ta (Tantalum).
Example 6 includes the subject matter of Example 5, wherein the layer comprising Ru and Ta operates as a top electrode for the MTJ resistor, and the SOT layer operates as a bottom electrode for the MTJ resistor.
Example 7 includes the subject matter of any one of Examples 2-6, wherein the resistance of the MTJ resistor fluctuates at a timescale of less than 10 nanoseconds.
Example 8 includes the subject matter of any one of Examples 1-7, wherein a distribution of outputs of the p-bits has a Gaussian distribution.
Example 9 is an integrated circuit component comprising the subject matter of any one of Examples 1-8.
Example 10 is a velocity sensor system or movement sensor system comprising the integrated circuit component of Example 9 and one or more memory devices.
Example 11 is an apparatus comprising: a plurality of a probabilistic bits (p-bits), wherein individual p-bits comprise a magnetic tunnel junction (MTJ) resistor and circuitry that converts a fluctuating resistance of the MTJ resistor into an output value; a learning circuit to receive an input from the output value of the individual p-bits and generate therefrom respective weights; and an interconnect circuit to apply the respective weights on nodes and provide therefrom an output to the input of the individual p-bits;
wherein the individual p-bits depends on the output of other p-bits of the plurality of p-bits.
Example 12 includes the subject matter of Example 11, wherein the plurality of p-bits represents an n-bit number.
Example 13 includes the subject matter of Example 12, wherein the n-bit number has a Gaussian distribution.
Example 14 includes the subject matter of any one of the Examples 11-13, wherein the individual p-bits of the plurality of p-bits further comprise a spin-orbit torque layer; wherein, in response to an applied current, the spin-orbit torque layer of the individual p-bits of the plurality of p-bits bias a voltage output of a corresponding p-bit.
Example 15 is an integrated circuit component comprising the apparatus of any one of Examples 11-14.
Example 16 is a system comprising the subject matter of Example 15 and one or more memory devices.
Example 17 is an apparatus comprising: one or more magnetic tunnel junctions; and means for using the one or more magnetic tunnel junctions to generate non-uniform random numbers.
Example 18 includes the subject matter of Example 17, wherein the means for using the one or more magnetic tunnel junctions to generate the non-uniform random numbers comprises a means for converting a fluctuating resistance of the magnetic tunnel junction into a binary value.
Example 19 includes the subject matter of Example 18, wherein the means for using the one or more magnetic tunnel junctions to generate the non-uniform random numbers further generates a respective voltages, and further comprising a means for learning to receive the respective voltages and convert them into respective resistance values.
Example 20 is a means for sensing movement comprising the subject matter of Example 19.

What is claimed is:

1. A random number generator (RNG) comprising:
a plurality of probabilistic bits (p-bits), wherein individual p-bits comprise:
a spin-orbit torque (SOT) layer;
a magnetic tunnel junction (MTJ) resistor attached orthogonal to the SOT layer; and
circuitry to convert a fluctuating resistance of the MTJ resistor into a binary value.

2. The random number generator (RNG) of claim 1, wherein the circuitry comprises:
a reference resistor having a first terminal, a second terminal, and a resistance equal to an average resistance of the MTJ resistor;
a voltage source;
the reference resistor attached at the first terminal to the voltage source, and attached at the second terminal to the MTJ resistor;
a ground source attached to the SOT layer; and
an inverter to invert a voltage at the second terminal.

3. The random number generator (RNG) of claim 1, wherein the MTJ resistor comprises a tunnel barrier layer sandwiched between a synthetic antiferromagnetic (SAF) layer and a SAF-free layer.

4. The random number generator (RNG) of claim 3, wherein the tunnel barrier layer comprises MgO (magnesium oxide).

5. The random number generator (RNG) of claim 1, wherein the MTJ resistor comprises a layer comprising Ruthenium (Ru) and Tantalum (Ta).

6. The random number generator (RNG) of claim 5, wherein the layer comprising Ru and Ta operates as a top electrode for the MTJ resistor, and the SOT layer operates as a bottom electrode for the MTJ resistor.

7. The random number generator (RNG) of claim 1, wherein the resistance of the MTJ resistor fluctuates at a timescale of less than 10 nanoseconds.

8. The random number generator (RNG) of claim 1, wherein a distribution of outputs of the p-bits has a Gaussian distribution.

9. An integrated circuit component comprising the random number generator (RNG) of claim 1.

10. A velocity sensor system or movement sensor system comprising the integrated circuit component of claim 9 and one or more memory devices.

11. An apparatus comprising:
a plurality of a probabilistic bits (p-bits), wherein individual p-bits comprise a magnetic tunnel junction (MTJ) resistor and circuitry that converts a fluctuating resistance of the MTJ resistor into an output value;
a learning circuit to receive an input from the output value of the individual p-bits and generate therefrom respective weights; and
an interconnect circuit to apply the respective weights on nodes and provide therefrom an output to the input of the individual p-bits;
wherein the individual p-bits depends on the output of other p-bits of the plurality of p-bits.

12. The apparatus of claim 11, wherein the plurality of p-bits represents an n-bit number.

13. The apparatus of claim 12, wherein the n-bit number has a Gaussian distribution.

14. The apparatus of claim 11, wherein the individual p-bits of the plurality of p-bits further comprise a spin-orbit torque layer;
wherein, in response to an applied current, the spin-orbit torque layer of the individual p-bits of the plurality of p-bits bias a voltage output of a corresponding p-bit.

15. An integrated circuit component comprising the apparatus of claim 11.

16. A system comprising the integrated circuit component of claim 15 and one or more memory devices.

17. An apparatus comprising:
one or more magnetic tunnel junctions; and
means for using the one or more magnetic tunnel junctions to generate non-uniform random numbers.

18. The apparatus of claim 17, wherein the means for using the one or more magnetic tunnel junctions to generate the non-uniform random numbers comprises a means for converting a fluctuating resistance of the magnetic tunnel junction into a binary value.

19. The apparatus of claim 18, wherein the means for using the one or more magnetic tunnel junctions to generate the non-uniform random numbers further generates a respective voltages, and further comprising a means for learning to receive the respective voltages and convert them into respective resistance values.

20. A means for sensing movement comprising the apparatus of claim 19.
